(19) United States
(12) Patent Application Publication
(10) Pub. No.: US 2026/0044069 A1
(43) Pub. Date: Feb. 12, 2026

(54) COPPER PILLAR CO-PLANARITY USING DIGITAL LITHOGRAPHY

(71) Applicant: Applied Materials, Inc., Santa Clara, CA (US)

(72) Inventors: Qin ZHONG, Santa Clara, CA (US); Guan-Shian CHEN, Sunnyvale, CA (US)

(21) Appl. No.: 19/285,084

(22) Filed: Jul. 30, 2025

Related U.S. Application Data
(60) Provisional application No. 63/679,691, filed on Aug. 6, 2024.

(51) Int. Cl. G03F 1/44; G03F 7/00; H01L 23/00

(52) U.S. Cl. CPC G03F 1/44; G03F 7/0012; G03F 7/0035; G03F 7/70291; G03F 7/70625; H01L 24/11; H01L 2224/11464

(57) ABSTRACT

In one or more embodiments, a method includes conducting a first digital lithography process according to a mask pattern to form first vias having a first dimension over a first area and second vias having a second dimension over a second area of a first substrate, the first dimension and the second dimension are different. The method further includes receiving metrology data of first pillars and second pillars. The first pillars and the second pillars having different heights. A digital lithography device generates an updated mask pattern according to the metrology data. The method further includes conducting a second digital lithography process according to the updated mask pattern to form third vias having a third dimension over the first area and fourth vias having a fourth dimension over the second area of a second substrate, the third dimension and the fourth dimension are different.

### CROSS-REFERENCE TO RELATED APPLICATIONS

This application claims priority to United States Provisional Patent Application serial no. No. 63/679,691, filed Aug. 6, 2024, which is herein incorporated by reference.

### BACKGROUND

### Field

Embodiments of the present disclosure generally relate to lithography systems. More particularly, embodiments of the present disclosure relate to a system, a software application, and methods of digital lithography for semiconductor packaging.

### Description of the Related Art

Electronic packaging and assembly are typically used to link the small dimensions of an integrated circuit (IC) to an interconnecting substrate, for example, a printed circuit board (PCB) or an interposer. The PCB usually includes a number of passive components and ICs to build a microelectronic device, and the interposer is a connection board embedded into a packaged chip with a plurality of chiplet ICs on the interposer. As the semiconductor industry has experienced rapid growth due to ongoing improvements in the integration density of a variety of electronic components, for example, transistors, diodes, resistors, and capacitors. For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

For the foregoing reasons, there is a need for a system, a software application, and method of lithography for semiconductor packaging.

### SUMMARY

Embodiments of the present disclosure generally relate to lithography systems. More particularly, embodiments of the present disclosure relate to a system, a software application, and methods of digital lithography for semiconductor packaging.

In one or more embodiments, a method includes conducting a first digital lithography process according to a mask pattern to form first vias having a first dimension over a first area and second vias having a second dimension over a second area of a first substrate, the first dimension and the second dimension are different. The method further includes receiving metrology data of first pillars and second pillars. The first pillars and the second pillars having different heights. A digital lithography device generates an updated mask pattern according to the metrology data. The method further includes conducting a second digital lithography process according to the updated mask pattern to form third vias having a third dimension over the first area and fourth vias having a fourth dimension over the second area of a second substrate, the third dimension and the fourth dimension are different.

In one or more embodiments, a method includes generating a mask pattern configured to pattern a photoresist in a digital lithography process. The method further includes conducting the digital lithography process according to the mask pattern to form first vias having a first dimension over a first area and second vias having a second dimension over a second area of a substrate. The first dimension and the second dimension are different.

In one or more embodiments, a non-transitory computer-readable medium includes instructions that, when executed by a processor, cause a computer system to conduct a first digital lithography process according to a mask pattern to form first vias having a first dimension over a first area and second vias having a second dimension over a second area of a first substrate. The first dimension and the second dimension are different. The instructions further include, receiving metrology data of first pillars and second pillars. The first pillars and the second pillars having different heights. A digital lithography device generates an updated mask pattern according to the metrology data. The instructions further include conducting a second digital lithography process according to the updated mask pattern to form third vias having a third dimension over the first area and fourth vias having a fourth dimension over the second area of a second substrate. The third dimension and the fourth dimension are different.

In one or more embodiments, a non-transitory computer-readable medium includes instructions that, when executed by a processor, cause a computer system to generate mask pattern configured to pattern a photoresist in a digital lithography process. The instructions further include conducting the digital lithography process according to the mask pattern to form first vias having a first dimension over a first area and second vias having a second dimension over a second area of a substrate. The first dimension and the second dimension are different.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram of a lithography system, according to one or more embodiments.

FIG. 2 is a perspective view of a digital lithography device, according to one or more embodiments.

FIG. 3 is a schematic cross sectional view of a packaging assembly, according to one or more embodiments.

FIG. 4 is a flow diagram of a method for forming the packaging assembly, according to one or more embodiments.

FIGS. 5A-5F are schematic, cross-sectional views of a substrate during a method for forming a packaging assembly, according to one or more embodiments.

FIG. 6 is a flow diagram of a first digital connection method, according to one or more embodiments.

FIG. 7 is a flow diagram of a second digital connection method, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to lithography systems. More particularly, embodiments of the present disclosure relate to a system, a software application, and methods of digital lithography for semiconductor packaging.

In the advanced packaging industry, pillars in a semiconductor package are formed by placing a substrate having a desired design patterned in a photoresist, in an electrolyte bath, where metal ions are deposited within vias patterned in the photoresist. For proper electrical connection, each of the pillars in the semiconductor package need to have an equivalent height. However, the deposition rate of the metal ions varies across the substrate, which causes the pillars to have uneven heights. Multiple factors affect the deposition rate of the metal ions within each of the vias while the substrate is in the electrolyte bath. These factors include a via density, the diameter of the vias, and the depth of the vias. Therefore, the design patterned in the photoresist may be changed or updated to generate an updated pattern in order to account for the factors that cause uneven deposition rates within each of the vias. This updated pattern causes an equal deposition rate within each of the vias, which causes each of the pillars formed within the vias to have equivalent heights.

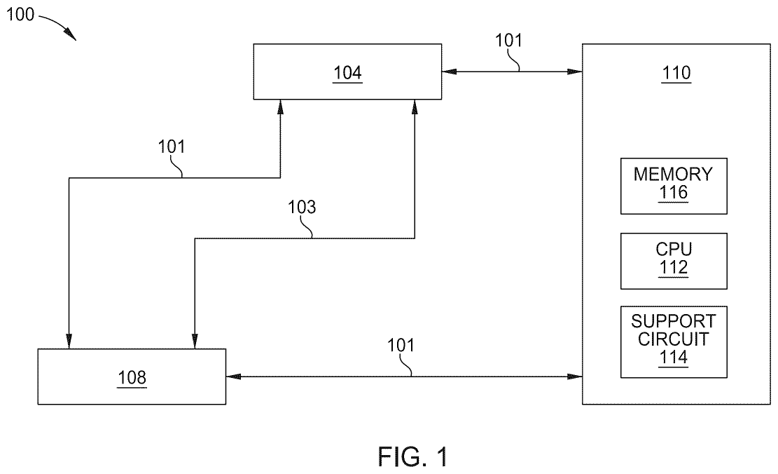

FIG. 1 is a schematic diagram of a lithography system 100. As shown, the lithography system 100 includes, but is not limited to, a metrology device 104, a digital lithography device 108, a controller 110, and a plurality of communication links 101. The lithography system 100 may further include a transfer system 103. The digital lithography device 108 and the metrology device 104 may be connected by the transfer system 103. The transfer system is operable to transfer a substrate between the digital lithography device 108 and the metrology device 104.

Each of the lithography system devices (the metrology device 104, the digital lithography device 108, and the controller 110) are operable to be connected to each other via the communication links 101. Alternatively or additionally, each of the lithography system devices can communicate indirectly by first communicating with the controller 110, followed by the controller 110 communicating with the lithography system device in question. The lithography system 100 can be located in the same area or production facility, or the each of the lithography system devices can be located in different areas.

Each of the plurality of lithography system devices are additionally indexed with digital connection methods 600, 700. Each of the metrology device 104, the digital lithography device 108, and controller 110 include an on-board processor and memory, where the memory is configured to store instructions corresponding to any portion of the methods 400, 600, 700 described below. The communication links 101 may include at least one of wired connections, wireless connections, satellite connections, and the like. The communications links 101 facilitate sending and receiving files to store data, according to embodiments further described herein. Transfer of data along communications links 101 can include temporarily or permanently storing files or data in the cloud, before transferring or copying the files or data to a lithography environment device.

The controller 110 includes a central processing unit (CPU) 112, support circuits 114 and memory 116. The CPU 112 can be one of any form of computer processor that can be used in an industrial setting for controlling the lithography system devices. The memory 116 is coupled to the CPU 112. The memory 116 can be one or more of readily available memory, such as random access memory (RAM), read only memory (ROM), floppy disk, hard disk, or any other form of digital storage, local or remote. The support circuits 114 are coupled to the CPU 112 for supporting the processor in a conventional manner. These circuits include cache, power supplies, clock circuits, input/output circuitry, subsystems, and the like. The controller 110 can include the CPU 112 that is coupled to input/output (I/O) devices found in the support circuits 114 and the memory 116. The controller 110 is operable to facilitate and transfer a design file to the digital lithography device 108 via the communication links 101.

The memory 116 can include one or more software applications, such as a controlling software program. The memory 116 can also include stored media data that is used by the CPU 112 to perform the methods described herein. The CPU 112 can be a hardware unit or combination of hardware units capable of executing software applications and processing data. In some configurations, the CPU 112 includes a central processing unit (CPU), a digital signal processor (DSP), an application-specific integrated circuit (ASIC), and/or a combination of such units. The CPU 112 is generally configured to execute the one or more software applications and process the stored media data, which can be each included within the memory 116. The controller 110 controls the transfer of data and files to and from the various lithography system devices. The memory 116 is configured to store instructions corresponding to any operation of the digital connection methods 600, 700 according to embodiments described herein.

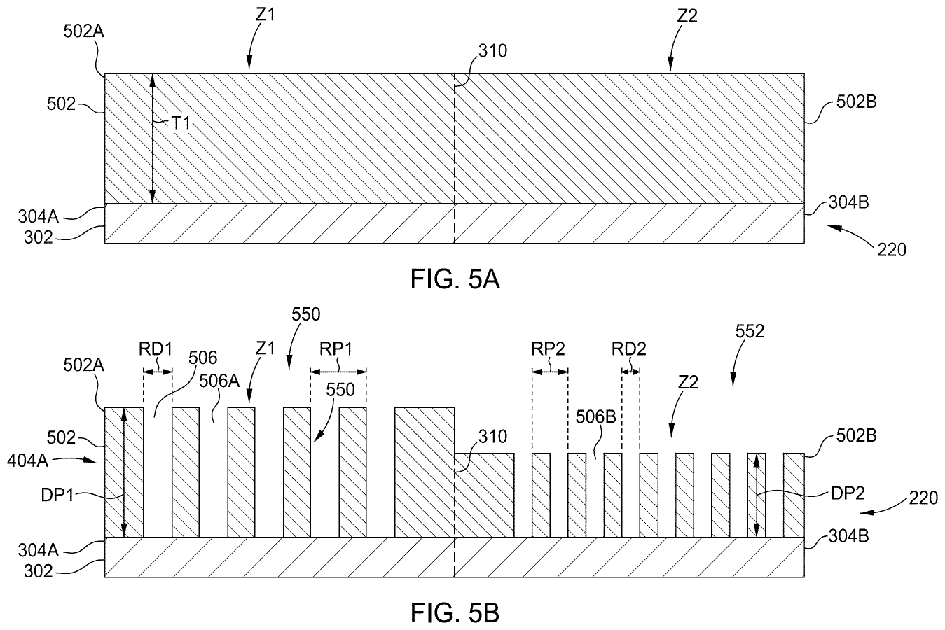

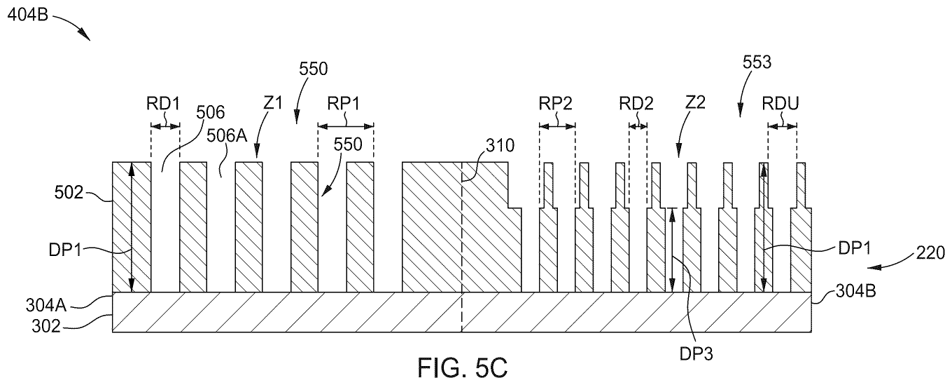

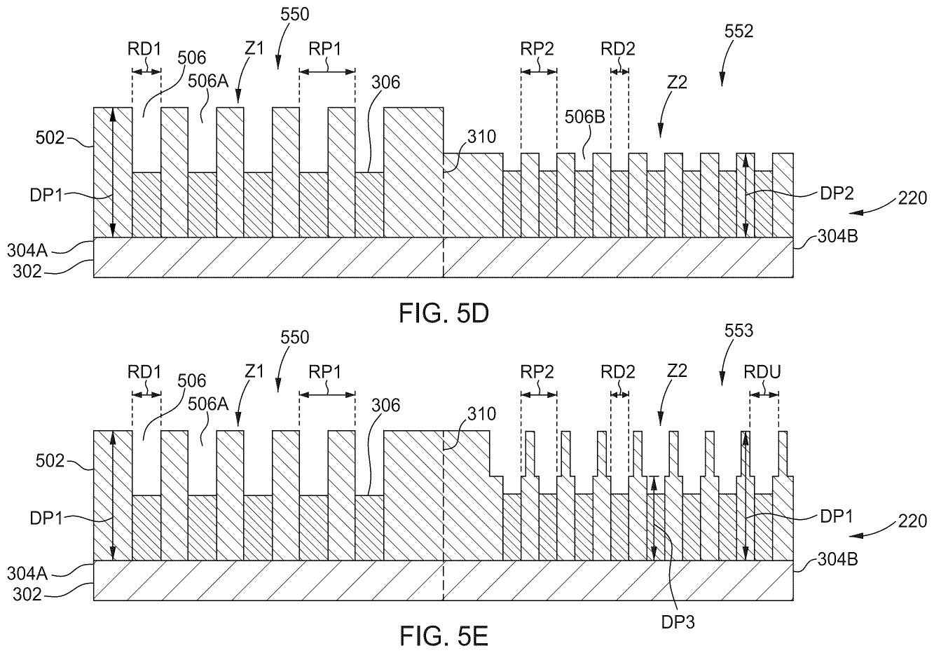

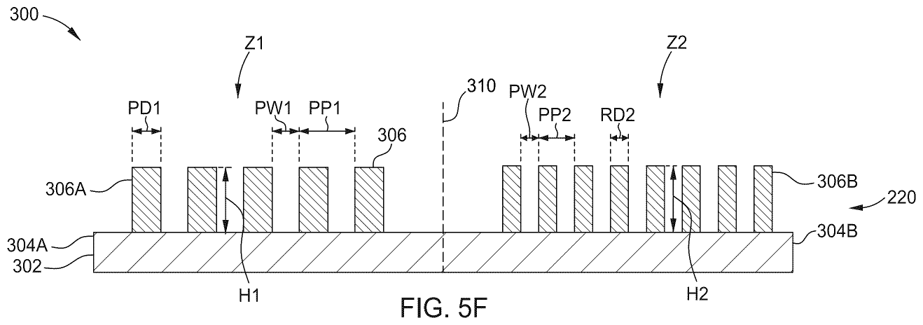

The metrology device 104 may include software and hardware to measure one or more variables. The one or more variables include at least one of a diameter of one or more vias 506 in a photoresist 502, a depth of one or more vias 506 in a photoresist 502, a pitch between each of the vias 506 within the photoresist 502, a width between each of the vias 506 witnin the photoresist 502, or a via density in at least a portion of a photoresist 502 as described in the corresponding description for FIG. 5B. The photoresist 502 may be a spin-on photoresist. The photoresist 502 is disposed via a spin-on process from the substrate center to edge. The thickness of the photoresist 502 varies from the spin-on process leading to a different via aspect ratios of the vias 506. The methods provided herein including the digital lithography processes provide for increased uniformity. The via density is defined by the number of vias 506 within a certain area. The one or more variables further include a diameter of one or more pillars 306 disposed on a packaging substrate 220, a height of the one or more pillars 306 disposed on a packaging substrate 220, a pitch between each pillar 306 disposed on the packaging substrate 220, a width between each pillar 306 disposed on a packaging substrate 220, and a pillar density in at least a portion substrate as described in the corresponding description for FIG. 5F. The metrology device 104 measures the one or more variables and converts the measurements into a format, and transfers the data to the controller 110. The metrology data generated from the metrology device 104 may be sent to the controller 110 via the communication link 101. The controller 110 may generate an updated mask pattern with the metrology data generated via the metrology device 104 (as shown in FIGS. 5B and 7C). The packaging substrate 220 may be a panel or a wafer dependent upon the end-device.

The updated mask pattern data is sent from the controller 110 to the digital lithography device 108 via the communication link 101. The digital lithography device 108 may include software and/or hardware to load a substrate, perform patterning process that results in a pattered resist after devolvement as described in FIGS. 5B and 5C. The photoresist 502 is disposed via a spin-on process from the substrate center to edge. The thickness of the photoresist 502 varies from the spin-on process leading to a different via aspect ratios of the vias 506. The methods provided herein including the digital lithography processes provide for increased uniformity.

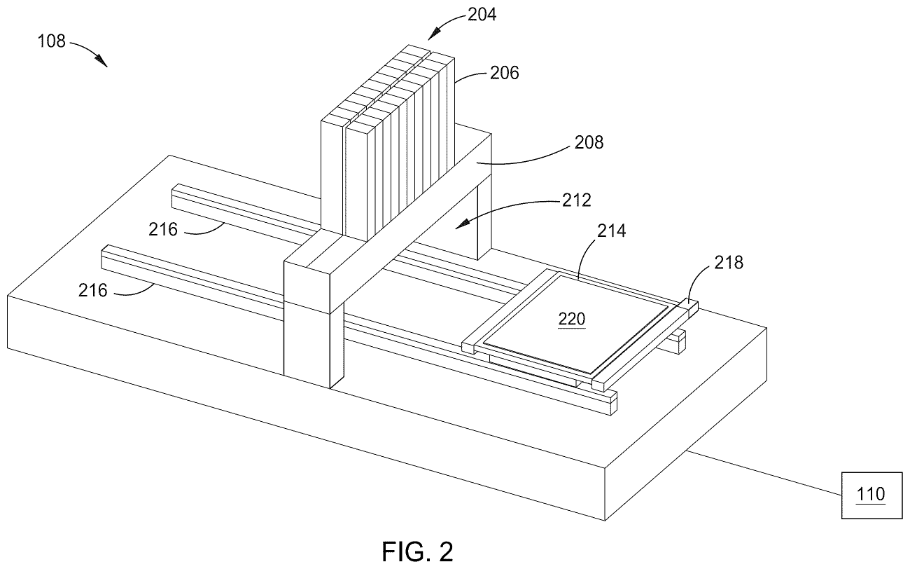

FIG. 2 is a perspective view of a digital lithography device 108, such as a digital lithography system, that may benefit from embodiments described herein. The digital lithography device 108 includes a stage 214 and a processing unit 204. The stage 214 is supported by a pair of tracks 216. A packaging substrate 220 is supported by the stage 214. The stage 214 is operable to move along the pair of tracks 216. An encoder 218 is coupled to the stage 214 in order to provide information of the location of the stage 214 to a controller 110.

The controller 110 is generally designed to facilitate the control and automation of the processing techniques described herein. The controller 110 may be coupled to or in communication with the processing unit 204, the stage 214, and the encoder 218. The processing unit 204 and the encoder 218 may provide information to the controller 110 regarding the substrate processing and the substrate aligning. For example, the processing unit 204 may provide information to the controller 110 to alert the controller 110 that substrate processing has been completed. A design file (or computer instructions), which may be referred to as an imaging design file, readable by the controller 110, determines which tasks are to be performed on a substrate. The design file includes a mask pattern data. The mask pattern data includes a mask pattern and code to monitor and control the processing time and substrate position. The mask pattern corresponds to a pattern to be written using the electromagnetic radiation.

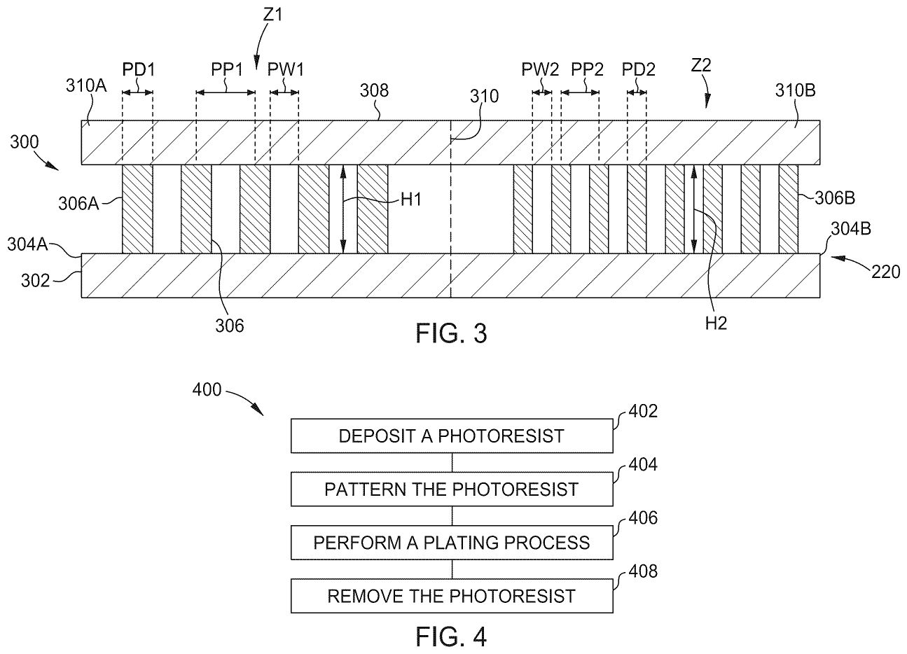

The packaging substrate 220 comprises any suitable material. The packaging substrate 220 includes a substrate 302, and one or more areas 304A, 304B (FIG. 3). A photoresist is disposed on the packaging substrate 220 to be patterned, which is sensitive to electromagnetic radiation, for example UV or deep UV “light”. The first photoresist can be either a positive photoresist or a negative photoresist. A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when unexposed to radiation, are respectively soluble to a photoresist developer applied to the photoresist after the pattern is written into the first photoresist using the electromagnetic radiation. After exposure of the photoresist 502 to the electromagnetic radiation, the photoresist 502 is developed to leave a patterned photoresist, the patterned photoresist including one or more vias 506 formed within the photoresist 502.

The processing unit 204 is supported by the support 208 such that the processing unit 204 straddles the pair of tracks 216. The support 208 provides an opening 212 for the pair of tracks 216 and the stage 214 to pass under the processing unit 204. The processing unit 204 is a pattern generator configured to receive the mask pattern data from the controller 110 and expose the photoresist 502 in the maskless lithography process using one or more image projection systems 206 operable to project write beams of electromagnetic radiation to the packaging substrate 220. The maskless lithography process includes grey tone lithography processes. The pattern generated by the processing unit 204 is projected by the image projection systems 206 to expose the photoresist of the packaging substrate 220 to the mask pattern that is written into the photoresist. In one embodiment, which can be combined with other embodiments described herein, each image projection system 206 includes a spatial light modulator to modulate the incoming light to create the desired image. Each spatial light modulator includes a plurality of electrically addressable elements that may be controlled individually. Each electrically addressable element may be in an “ON” position or an “OFF” position based on the mask pattern data and updated mask pattern data provided by correction models created through the methods 600, 700 described herein. When the light reaches the spatial light modulator, the electrically addressable elements that are in the “ON” position project a plurality of write beams to a projection lens (not shown). The projection lens then projects the write beams to the packaging substrate 220. The electrically addressable elements include, but are not limited to, digital micromirrors, liquid crystal displays (LCDs), liquid crystal over silicon (LCoS) devices, ferroelectric liquid crystal on silicon (FLCoS) devices, microshutters, microLEDs, VCSELs, liquid crystal displays (LCDs), or any solid state emitter of electromagnetic radiation.

FIG. 3 is a schematic cross sectional view of a packaging assembly 300, according to one or more embodiments. The packaging assembly 300 includes the packaging substrate 220. The packaging substrate 220 includes a substrate 302 having a first area 304A and a second area 304B. The packaging assembly 300 further include multiple pillars 306 disposed over the first area 304A and the second area 304B. The pillars 306 form a first plurality of pillars 306A, a second plurality of pillars 306B. A connecting structure 308 is disposed on the pillars 306 of the packaging assembly 300. The substrate 302 may be a panel or a wafer dependent upon the end-device.

The packaging assembly 300 has two zones. The two zones include a first zone Z1 and a second zone Z2. The first zone Z1 and the second zone Z2 are divided by a separation line 310. It should be understood that the separation line 310 is only shown for illustrative purposes. The first zone Z1 includes the first area 304A and the first plurality of pillars 306A. The packaging assembly 300 shows the first plurality of pillars 306A including five pillars 306, however, it should be understood that the first plurality of pillars 306A could include any number of pillars 306. The first zone Z1 has a first pillar density. The first pillar density is defined by the number of pillars 306 within the first zone Z1. Each pillar 306 in the first plurality of pillars 306A includes a first height H1 and a first pillar critical dimension PD1. The first pillar critical dimension PD1 can a diameter or a width of the pillar 306. Each pillar 306 in the first plurality of pillars 306A are separated by a first pillar width PW1. The center of each pillar 306 in the first plurality of pillars 306A is separated by a first pillar pitch PP1.

The second zone Z2 includes the second area 304B and the second plurality of pillars 306B. The packaging assembly 300 shows the second plurality of pillars 306B including eight pillars 306, however, it should be understood that the second plurality of pillars 306B could include any number of pillars 306. The second zone Z2 has a second pillar density. The second pillar density is higher than the first pillar density. Each pillar 306 in the second plurality of pillars 306B includes a second height H2 and a second pillar critical dimension PD2. The second pillar critical dimension PD2 can a diameter or a width of the pillar 306. Each pillar 306 in the second plurality of pillars 306B is separated by a second pillar width W2. The center of each pillar 306 in the second plurality of pillars 306B is separated by a second pillar pitch PP2. The first height H1 and the second height H2 are equivalent so that the connecting structure 308 contacts every pillar 306 in both the first plurality of pillars 306A and the second plurality of pillars 306B. The connecting structure includes a first die area 310A and a second die area 310B. In one or more embodiments, the first die area 310A and the second die area 310B are separate individual die. In one or more embodiments, the first die area 310A and the second die area 310B are portions of a single die that is connected. Each pillar 306 in the first plurality of pillars 306A and the second plurality of pillars 306B are formed of a metal material. In one or more embodiments, the metal material is a copper material.

FIG. 4 is a flow diagram of a method 400 for forming the packaging assembly 300, according to one or more embodiments. FIGS. 5A-5F are schematic, cross-sectional views of a substrate 302 during a method 400 for forming a packaging assembly, according to embodiments.

At operation 402 of the method 400, as shown in FIG. 5A, a photoresist 502 is deposited over the packaging substrate 220. The packaging substrate 220 is separated into a first zone Z1 and a second zone Z2 which is separated by the separation line 310. The first zone Z1 includes the first area 304A. The second zone includes the second area 304B. A first portion 502A of the photoresist 502 is deposited in the first zone Z1. A second portion 502B of the photoresist 502 is deposited in the second zone Z2. The photoresist 502 has a thickness T1 defined by the distance between a top surface of the first area 304A and/or the second area 304B, and a top surface of the photoresist 502.

At operation 404 of the method 400, as shown in FIGS. 5B and 5C, the photoresist 502 is patterned with one or more patterns using the digital lithography device 108. The one or more patterns is determined by the mask pattern data or updated mask pattern data received from the controller 110. FIG. 5B shows the photoresist 502 patterned with one or more patterns according to a first sub-method 404A. FIG. 5C shows the photoresist 502 patterned with one or more patterns according to a second sub-method 404B. In the first sub-method 404A, as shown in FIG. 5B, the controller 110 sends the masked pattern data to the digital lithography device 108. The mask pattern data includes the instructions for the digital lithography device 108 to pattern the first portion 502A of the photoresist 502 deposited in the first zone Z1 with a first pattern 550, and pattern the second portion of the photoresist 502 deposited in the second zone Z2 with a second pattern 552 using greyscale lithography. The first pattern 550 has a first number of vias 506. The vias 506 are openings patterned in the photoresist 502. The first zone Z1 includes a first plurality of vias 506A. FIG. 5B shows the first plurality of vias 506A including five vias 506, however, it should be understood that the first plurality of vias 506A could include any number of vias 506. Each via 506 in the first plurality of vias 506A has a first resist critical dimension RD1. Each via 506 in the first plurality of vias 506A is separated by a first resist pitch PP1. The second pattern 552 has a second number of vias 506. The second zone Z2 includes a second plurality of vias 506B. FIG. 5B shows the second plurality of vias 506B including eight vias 506, however, it should be understood that the second plurality of vias 506B could include any number of vias 506. Each via 506 in the second plurality of vias 506B has a second resist critical dimension RD2. The first resist critical dimension RD1 is greater than the second resist critical dimension RD2. Each via 506 in the second plurality of vias 506B is separated by a second resist pitch RP2. The via density in the first zone Z1 is greater than the via density in the second zone Z2. The first resist critical dimension RD1 is equivalent to the first pillar critical dimension PD1. The second resist critical dimension RD2 is equivalent to the second pillar critical dimension PD2.

The different resist critical dimensions RD1, RD2, resist pitches RP1, RP2, and via densities between the first zone Z1 and the second zone Z2 cause a first deposition rate deposition rate in the first zone Z1 to be different from a second deposition rate in the second zone Z2 during a plating process in an electrolyte bath. In the first sub-method 404A as shown in FIG. 5B, the first pattern 550 causes first plurality of vias 506 have a first depth DP1. In some embodiments the first depth DP1 is equivalent to the thickness T1. The second pattern 552 reduces the thickness T1 of the second portion 502B of the photoresist 502 during the greyscale lithography process. The reduced thickness causes the second pattern 552 to have a second depth DP2. The second depth DP2 is less than the first depth DP1. The difference between the second depth DP2 and the first depth DP1 causes the first deposition rate and the second deposition rate to be equivalent during the plating process. Both the first depth DP1 and the second depth DP2 are greater than the heights H1, H2 of the pillars formed in the vias 506.

In the second sub-method 404B, as shown in FIG. 5C, the controller 110 sends the masked pattern data to the digital lithography device 108. The mask pattern data includes the instructions for the digital lithography device 108 to pattern the first portion 502A of the photoresist 502 deposited in the first zone Z1 with a first pattern 550, and pattern the second portion of the photoresist 502 deposited in the second zone Z2 with a second pattern 552 using greyscale lithography. The first pattern 550 has a first number of vias 506. The vias 506 are openings patterned in the photoresist 502. The first zone Z1 includes a first plurality of vias 506A. FIG. 5B shows the first plurality of vias 506A including five vias 506, however, it should be understood that the first plurality of vias 506A could include any number of vias 506. Each via 506 in the first plurality of vias 506A has a first resist critical dimension RD1. Each via 506 in the first plurality of vias 506A is separated by a first resist pitch PP1. The first portion 502A of the photoresist is patterned with the first pattern 550. The second portion 502B of the photoresist 502 is patterned with the third pattern. The second zone Z2 includes a second plurality of vias 506B. FIG. 5C shows the second plurality of vias 506B including eight vias 506, however, it should be understood that the second plurality of vias 506B could include any number of vias 506. Each via 506 in the second plurality of vias 506B has a lower resist critical dimension RDL. The first resist critical dimension RD1 is greater than the lower resist critical dimension RDL. Each via 506 in the second plurality of vias 506B is separated by a lower resist pitch RPL. The via density in the first zone Z1 is greater than the via density in the second zone Z2. The first resist critical dimension RD1 is equivalent to the first pillar critical dimension PD1. The lower resist critical dimension RDL is equivalent to the second pillar critical dimension PD2. The vias 506 in the first plurality of vias 506A and the second plurality of vias 506B have a first via depth DP1.

The different resist critical dimensions RD1, RD2, resist pitches RP1, RP2, and via densities between the first zone Z1 and the second zone Z2 cause a first deposition rate deposition rate in the first zone Z1 to be different from a second deposition rate in the second zone Z2 during a plating process in an electrolyte bath. In the second sub-method 404B as shown in FIG. 5C, the third pattern 553 causes an upper portion of the second plurality of vias 506B to have an upper resist critical dimension RDU. The upper resist critical dimension RDU is different from the lower resist critical dimension RDL. For example in FIG. 5C, the upper resist critical dimension RDU is larger than the lower resist critical dimension RDL. The upper resist critical dimension RDU is larger than the first resist critical dimension RD1. The upper resist critical dimension RDU being larger than the first resist critical dimension RD1 causes the first deposition rate to be equivalent to the second deposition rate during a plating process. A third depth DP3 is defined by the depth of the portion of the via 506 having the lower resist critical dimension RDL. Both the first depth DP1 and the third depth DP3 are greater than the heights H1, H2 of the pillars formed in the vias 506.

In one or more embodiments, during operation 402 when the photoresist 502 is applied to the packaging substrate 220, the photoresist 502 has a varying thickness. Both the first-sub-method 404A and the second sub-method 404B of operation 404 can be performed to planarize the photoresist so that the first zone Z1 has a uniform first thickness and the second zone Z2 has a uniform second thickness.

At operation 406 of the method 400, as shown in FIGS. 5D and 5E, pillars 306 are formed within the vias 506. The pillars 306 are formed by placing the substrate 302 after operation 408 into an electrolyte bath, the electrolyte bath including metal ions. The metal ions include copper ions. While the substrate 302 is in the electrolyte bath, the metal ions are deposited within the vias 506 in both the first plurality of vias 506A and the second plurality of vias 506B to form the pillars 306. FIG. 5D shows the packaging substrate 220 patterned with the first pattern 550 and the second pattern 552 formed in the first sub-method 404A as shown in FIG. 5B. FIG. 5E shows the packaging substrate 220 patterned with the first pattern 550 and the third pattern 553 the second sub-method 404B as shown in FIG. 5C.

At operation 408 of the method 400, as shown in FIG. 5F, photoresist 502 is removed forming the packaging assembly 300. The pillars 306 that were deposited in the first plurality of vias 506A form the first plurality of pillars 306A. The pillars 306 that were deposited in the second plurality of vias 506B form the second plurality of pillars 306B. The pillars 306 in the first plurality of pillars 306A have the first height H1. The pillars in the second plurality of pillars 306B have the second height H2. The first height H1 and the second height H2 are equivalent. In one or more embodiments, both the first height H1 and the second height H2 are less than the thickness of the photoresist 502.

In one or more embodiments, after operation 408 as further described in operation 704 of method 700 a metrology process is performed on the packaging assembly 300. The first height H1 and the second height H2 are measured by the metrology device 104 to obtain metrology data. If the first height H1 and the second height H2 are not within a predetermined tolerance of one another, then the metrology data is sent by the metrology device to the controller 110. The controller 110 may update the mask pattern data based on the metrology data sent from the metrology device 104.

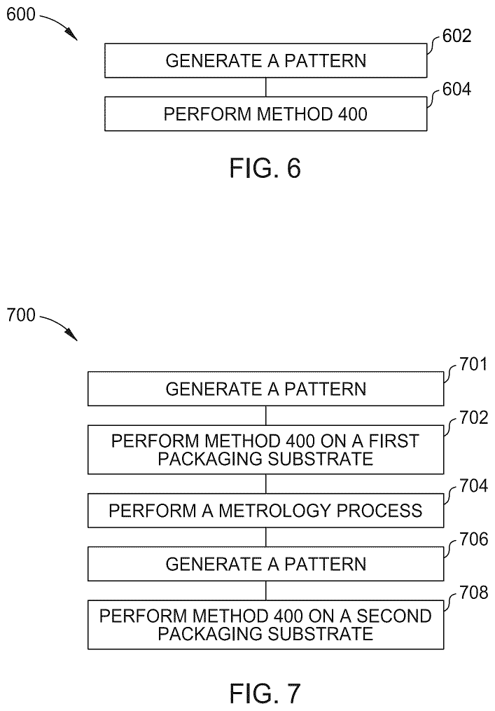

FIG. 6 is a flow diagram of a first digital connection method 600, according to one or more embodiments. In one or more embodiments, the method 600 is performed using the controller 110, the metrology device 104, and the digital lithography device 108. The method 600 can be performed in conjunction with the method 400.

At operation 602, the controller generates one or more mask patterns based on an input. A desired design for the packaging assembly is sent to the controller 110. The controller 110 generates one or more mask patterns based on the design of the packaging assembly and empirical data stored in the controller 110. For example, the controller 110 receives the design for packaging assembly 300 as shown in FIG. 3. The first zone Z1 and the second zone Z2 each have a different number of pillars 306 which results in a first pillar density in the first zone Z1 that is different from a second pillar density in the second zone Z2. Additionally, each of the pillars 306 in the first zone Z1 has a first pillar diameter PD1 and a first pillar pitch PP1. Each of the pillars 306 in the second zone Z2 has a second pillar diameter PD2 and a second pillar pitch PP2. The first pillar diameter PD1 is different from the second pillar diameter PD2. The first pillar pitch PP1 is different from the second pillar pitch PP2. The controller 110 interprets one or more variables such as, the different number of pillars 306 in the first zone Z1 and the second zone Z2, as well as the different pillar densities, pillar diameters PD1, PD2, and pillar pitches PP1, PP2 and calculates one or more patterns based of the one or more variables and empirical data stored in the controller 110. The one or more patterns generated by the controller 110 are calculated by the controller 110 cause the pillars in the first zone Z1 to have the same deposition rate as the pillars in the second zone Z2. Therefore, the pillars 306 in the first zone Z1 and the pillars in the second zone Z2 should have the same height after a plating process as described in operation 406 of method 400.

At operation 604, the method 400 is performed using the mask pattern generated in operation 602. A photoresist 502 is patterned with one or more patterns using the digital lithography device 108. The one or more patterns is determined by the mask pattern data generated by the controller 110 in operation 602. The photoresist 502 may be patterned using either the first sub-method 404A or the second sub-method 404B.

FIG. 7 is a flow diagram of a second digital connection method 700, according to one or more embodiments. In one or more embodiments, the method 700 is performed using the controller 110, the metrology device 104, and the digital lithography device 108. The method 700 can be performed in conjunction with the method 400 as described herein.

At operation 701, the controller generates one or more mask patterns based on an input. A desired design for the packaging assembly is sent to the controller 110. The controller 110 generates one or more mask patterns based on the design of the packaging assembly and empirical data stored in the controller 110. For example, the controller 110 receives the design for packaging assembly 300 as shown in FIG. 3. The first zone Z1 and the second zone Z2 each have a different number of pillars 306 which results in a first pillar density in the first zone Z1 that is different from a second pillar density in the second zone Z2. Additionally, each of the pillars 306 in the first zone Z1 has a first pillar diameter PD1 and a first pillar pitch PP1. Each of the pillars 306 in the second zone Z2 has a second pillar diameter PD2 and a second pillar pitch PP2. The first pillar diameter PD1 is different from the second pillar diameter PD2. The first pillar pitch PP1 is different from the second pillar pitch PP2. The controller 110 interprets one or more variables such as, the different number of pillars 306 in the first zone Z1 and the second zone Z2, as well as the different pillar densities, pillar diameters PD1, PD2, and pillar pitches PP1, PP2 and calculates one or more patterns based of the one or more variables and empirical data stored in the controller 110.

At operation 702, the method 400 is performed on a first packaging substrate using the mask pattern generated in operation 701. A photoresist 502 is patterned with one or more patterns using the digital lithography device 108. The one or more patterns is determined by the mask pattern data generated by the controller 110 in operation 701. The photoresist 502 may be patterned using either the first sub-method 404A or the second sub-method 404B. Operation 702 forms a first packaging assembly.

At operation 704, a metrology process is performed on the first packaging assembly formed in operation 702. During operation 704, the first diameter D1, the second diameter D2, the first height H1, the second height H2, the first pitch P1, the second pitch P2, the first pillar density, and/or the pillar via density of the first packaging assembly are measured by the metrology device 104 to obtain the metrology data. The metrology data is sent from the metrology device 104 to the controller 110.

At operation 706, an updated mask pattern is generated using the metrology data generated in operation 704. The updated mask pattern is generated by the controller 110, and the updated mask pattern data is sent to the digital lithography device 108 where processing unit 204 convert the corrective mask pattern data into one or more corrective patterns. The geometry of the corrective mask pattern is determined by the controller 110 in response to the metrology data received by the controller 110 along with empirical data stored in the controller 110. The corrective mask pattern is configured to form one or more updated patterns that causes the pillars 306 formed in both the first zone Z1 and the second zone Z2 in a packaging assembly to have an equivalent height.

At operation 708, the method 400 is performed on a second packaging substrate using the updated mask pattern generated in operation 706. A photoresist 502 is patterned with one or more patterns using the digital lithography device 108. The one or more patterns is determined by the updated mask pattern data generated by the controller 110 in operation 706. The photoresist 502 may be patterned using either the first sub-method 404A or the second sub-method 404B. Operation 702 forms a second packaging assembly.

It is contemplated that after operation 708 is performed, a second metrology process can be performed to determine whether a height of each pillar is within a predetermined tolerance of one another. If the height of each pillar is not within the predetermined tolerance of one another, then operations 704-708 can be repeated until height of each pillar is within a predetermined tolerance of one another.

Benefits of the present disclosure include a packaging assembly 300 having a first plurality of pillars 306A and a second plurality of pillars 306B having an equivalent height. The equivalent heights allows for all pillars 306 in the packaging assembly 300 to connect to a connecting structure 308. The device and methods of forming the device described herein allows for the manufacturing of a packaging assembly having an increased performance and increased quality, while decreasing the manufacturing time, and manufacturing costs.

It is contemplated that one or more aspects disclosed herein may be combined. As an example, one or more aspects, features, components, operations and/or properties of the lithography system 100, the metrology device 104, the digital lithography device 108, the controller 110, the communication links 101, the transfer system 103, the packaging substrate 220, the packaging assembly 300, the substrate 302, the first area 304A, the second area 304B, the first plurality of pillars 306A, the second plurality of pillars 306B, the connecting structure 308, the method 400, photoresist 502, the vias 506, the pillars 306, the method 600, and/or the method 700 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
conducting a first digital lithography process according to a mask pattern to form first vias having a first dimension over a first area and second vias having a second dimension over a second area of a first substrate, the first dimension and the second dimension are different;
receiving metrology data of first pillars and second pillars, the first pillars and the second pillars having different heights, a digital lithography device generates an updated mask pattern according to the metrology data; and
conducting a second digital lithography process according to the updated mask pattern to form third vias having a third dimension over the first area and fourth vias having a fourth dimension over the second area of a second substrate, the third dimension and the fourth dimension are different.

2. The method of claim 1, wherein a depth of the third vias is greater than a depth of the fourth vias.

3. The method of claim 1, wherein the fourth vias further comprise an upper dimension, wherein the upper dimension is larger than the third dimension.

4. The method of claim 1, wherein the first substrate and the second substrate are panels or wafers.

5. The method of claim 1, wherein the first pillars and second pillars are formed of a copper material.

6. The method of claim 1, further comprising:
performing a plating process using the updated mask pattern, the plating process comprising:
placing the second substrate after operation into an electrolyte bath, the electrolyte bath including metal ions; and
forming a plurality of pillars within the third vias and the fourth vias.

7. The method of claim 1, wherein a diameter of the third vias is less than a diameter of the fourth vias.

8. A method, comprising:
generating a mask pattern configured to pattern a photoresist in a digital lithography process; and
conducting the digital lithography process according to the mask pattern to form first vias having a first dimension over a first area and second vias having a second dimension over a second area of a substrate, the first dimension and the second dimension are different.

9. The method of claim 8, wherein a depth of the first vias is greater than a depth of the second vias.

10. The method of claim 8, wherein the second vias further comprise an upper dimension, wherein the upper dimension is larger than the first dimension.

11. The method of claim 8, wherein the substrate is a panel or a wafer.

12. The method of claim 8, further comprising:
performing a plating process using the mask pattern, the plating process comprising:
placing the second substrate after operation into an electrolyte bath, the electrolyte bath including metal ions; and
forming a plurality of pillars within the first vias and the second vias.

13. The method of claim 12, wherein the plurality of pillars are formed of a copper material.

14. A non-transitory computer-readable medium storing instructions that, when executed by a processor, cause a computer system to perform the steps of:
conducting a first digital lithography process according to a mask pattern to form first vias having a first dimension over a first area and second vias having a second dimension over a second area of a first substrate, the first dimension and the second dimension are different;
receiving metrology data of first pillars and second pillars, the first pillars and the second pillars having different heights, a digital lithography device generates an updated mask pattern according to the metrology data; and
conducting a second digital lithography process according to the updated mask pattern to form third vias having a third dimension over the first area and fourth vias having a fourth dimension over the second area of a second substrate, the third dimension and the fourth dimension are different.

15. The non-transitory computer-readable medium of claim 14, wherein a depth of the third vias is greater than a depth of the fourth vias.

16. The non-transitory computer-readable medium of claim 14, wherein the fourth vias further comprise an upper dimension, wherein the upper dimension is larger than the third dimension.

17. The non-transitory computer-readable medium of claim 14, wherein the first pillars and second pillars are formed of a copper material.

18. The non-transitory computer-readable medium of claim 14, further comprising:
performing a plating process using the updated mask pattern, the plating process comprising:
placing the second substrate after operation into an electrolyte bath, the electrolyte bath including metal ions; and
forming a plurality of pillars within the third vias and the fourth vias.

19. The non-transitory computer-readable medium of claim 14, wherein a diameter of the third vias is less than a diameter of the fourth vias.

20. The non-transitory computer-readable medium of claim 14, wherein the substrate is a panel or a wafer.
